(19) United States
(12) Patent Application Publication
(10) Pub. No.: US 2024/0304494 A1
(43) Pub. Date: Sep. 12, 2024

(54) METHOD OF MANUFACTURING SEMICONDUCTOR DEVICE, METHOD FOR SEPARATING SUBSTRATE, AND SUBSTRATE PROCESSING APPARATUS

(71) Applicant: Kioxia Corporation, Tokyo (JP)

(72) Inventors: Mariko SUMIYA, Yokkaichi Mie (JP); Mie MATSUO, Kamakura Kanagawa (JP)

(73) Assignee: Kioxia Corporation, Tokyo (JP)

(21) Appl. No.: 18/596,655

(22) Filed: Mar. 6, 2024

(30) Foreign Application Priority Data
Mar. 7, 2023 (JP) 2023-034659

(51) Int. Cl. H01L 21/762; B23K 26/03; B23K 26/08; H01L 21/18; H01L 21/268; H01L 21/683; H01L 21/8238

(52) U.S. Cl. CPC H01L 21/76259; B23K 26/0823; H01L 21/185; H01L 21/268; H01L 21/6838; H01L 21/8238; B23K 26/03

(57) ABSTRACT

A method of manufacturing a semiconductor device includes forming a bonded substrate including an effective chip area by bonding a first chip including a first device layer on a first substrate via a porous layer and a second chip including a second device layer on a second substrate, irradiating the porous layer in an ineffective chip area surrounding the effective chip area of the bonded substrate with laser light from the first substrate side, and separating the first substrate from the bonded substrate from the porous layer in the ineffective chip area.

### CROSS REFERENCE TO RELATED APPLICATION(S)

This application is based upon and claims the benefit of priority from the prior Japanese Patent Application JP2023-034659, filed on Mar. 7, 2023, the entire contents of which are incorporated herein by reference.

### FIELD

Embodiments of the present disclosure relate to a method of manufacturing a semiconductor device, a method for separating a substrate, and a substrate processing apparatus.

### BACKGROUND

A NAND flash memory is known as a semiconductor memory device. The NAND flash memory includes a memory cell array and its control circuit. A method in which the memory cell array chip and the control circuit chip are formed on separate substrates and bonded later is known as a method of manufacturing a semiconductor memory device. In this case, the substrate on which the memory cell array chip is formed can be reused after separation.

### BRIEF DESCRIPTION OF THE DRAWINGS

FIG. 1 is a diagram showing an overall configuration of a semiconductor memory device (bonded substrate) according to the present embodiment.

FIG. 2 is a top view showing a configuration of a semiconductor memory device (bonded substrate) according to the present embodiment.

FIG. 3 is a cross-sectional view showing a configuration of a semiconductor memory device (bonded substrate) according to the present embodiment.

FIG. 4 is a diagram showing an overall configuration of a semiconductor memory device according to the present embodiment.

FIG. 5A is a diagram showing a configuration and a forming method of a silicon layer according to the present embodiment.

FIG. 5B is a diagram showing a configuration and a forming method of a porous layer according to the present embodiment.

FIG. 6 is a top view showing a basic configuration of a substrate processing apparatus according to the present embodiment.

FIG. 7 is a side view showing a basic configuration of a processing apparatus according to the present embodiment.

FIG. 8A is a side view showing a basic configuration of a processing apparatus according to the present embodiment.

FIG. 8B is a top view showing a basic configuration of a processing apparatus according to the present embodiment.

FIG. 8C is a top view showing a basic configuration of a processing apparatus according to the modification.

FIG. 9A is a side view showing a basic configuration of a wafer hand according to the present embodiment.

FIG. 9B is a top view showing a configuration of a first arm according to the present embodiment.

FIG. 9C is a top view showing a configuration of a second arm according to the present embodiment.

FIG. 9D is a top view showing a configuration of a third arm according to the present embodiment.

FIG. 10 is a flowchart illustrating a method for separating a substrate according to the present embodiment.

FIG. 11A is a side view of a processing apparatus illustrating a method for separating a substrate according to the present embodiment.

FIG. 11B is a side view of a processing apparatus illustrating a method for separating a substrate according to the present embodiment.

FIG. 11C is a side view of a processing apparatus illustrating a method for separating a substrate according to the present embodiment.

FIG. 12 is a cross-sectional view showing a laser irradiation area of the semiconductor memory device (bonded substrate) according to the present embodiment.

FIG. 13A is a side view of a processing apparatus illustrating a method for separating a substrate according to the present embodiment.

FIG. 13B is a side view of a processing apparatus illustrating a method for separating a substrate according to the present embodiment.

FIG. 14A is a top view of a wafer hand illustrating a method for separating a substrate according to the present embodiment.

FIG. 14B is a side view of a wafer hand illustrating a method for separating a substrate according to the present embodiment.

FIG. 15A is a side view of a processing apparatus illustrating a method for separating a substrate according to the present embodiment.

FIG. 15B is a top view of a processing apparatus illustrating a method for separating a substrate according to the present embodiment.

FIG. 16A is a side view of a processing apparatus illustrating a method for separating a substrate according to the present embodiment.

FIG. 16B is a top view of a processing apparatus illustrating a method for separating a substrate according to the present embodiment.

FIG. 17A is a side view of a processing apparatus illustrating a method for separating a substrate according to the present embodiment.

FIG. 17B is a top view of a processing apparatus illustrating a method for separating a substrate according to the present embodiment.

FIG. 18 is a cross-sectional view showing a configuration of a semiconductor device according to the present embodiment.

FIG. 19 is a cross-sectional view showing a configuration of a semiconductor device according to the present embodiment.

FIG. 20A is a side view of a processing apparatus illustrating a method for separating a substrate according to the present embodiment.

FIG. 20B is a side view of a processing apparatus illustrating a method for separating a substrate according to the present embodiment.

FIG. 21A is a top view of a wafer hand illustrating a method for separating a substrate according to the present embodiment.

FIG. 21B is a side view of a wafer hand illustrating a method for separating a substrate according to the present embodiment.

FIG. 22A is a top view of a wafer hand illustrating a method for separating a substrate according to the present embodiment.

FIG. 22B is a side view of a wafer hand illustrating a method for separating a substrate according to the present embodiment.

FIG. 23A is a top view of a wafer hand illustrating a method for separating a substrate according to the present embodiment.

FIG. 23B is a side view of a wafer hand illustrating a method for separating a substrate according to the present embodiment.

### DESCRIPTION OF EMBODIMENTS

Hereinafter, a method of manufacturing a semiconductor device, a method for separating a substrate, and a substrate processing apparatus according to the present embodiment will be described in detail with reference to the drawings. In the following description, elements having substantially the same functions and configurations are denoted by the same reference signs or the same reference signs, followed by alphabetic characters, and will be described redundantly only when necessary. Each of the embodiments described below exemplifies an apparatus and a method for embodying a technical idea of this embodiment. Various modifications may be made to an embodiment without departing from the spirit of the invention. These embodiments and modifications thereof are included in the scope of the invention described in the claims and equivalents thereof.

In the drawings, the widths, thicknesses, shapes, and the like of the respective portions may be schematically represented in comparison with the actual embodiments for clarity of explanation, but the drawings are merely examples, and do not limit the interpretation of the present disclosure. In the present specification and the drawings, elements having the same functions as those described with respect to the above-described drawings are denoted by the same reference signs, and redundant descriptions thereof may be omitted.

In the embodiments, a direction from each substrate towards a memory cell or a control circuit is referred to as above. Conversely, a direction from the memory cell or the control circuit towards each substrate is referred to as below. As described above, for convenience of explanation, the term “above” or “below” is used to describe the configuration, but the configuration may be such that the vertical relationship between the substrate and the memory cell is opposite to that shown in the figure. In the following explanation, for example, the expression “memory cell on substrate” merely describes the vertical relationship between the substrate and the memory cell as described above, and another member may be arranged between the substrate and the memory cell.

In the present specification, the expression “a includes A, B, or C” does not exclude the case where a includes a plurality of combinations of A to C unless otherwise specified. Furthermore, these expressions do not exclude the case where a includes other elements.

The following embodiments can be combined with each other as long as there is no technical contradiction.

A method of manufacturing a semiconductor device includes forming a bonded substrate including an effective chip area by bonding a first chip including a first device layer on a first substrate via a porous layer and a second chip including a second device layer on a second substrate, irradiating the porous layer in an ineffective chip area surrounding the effective chip area of the bonded substrate with laser light from the first substrate side, and separating the first substrate from the bonded substrate from the porous layer in the ineffective chip area.

### First Embodiment

### [Semiconductor Memory Device (Bonded Substrate)]

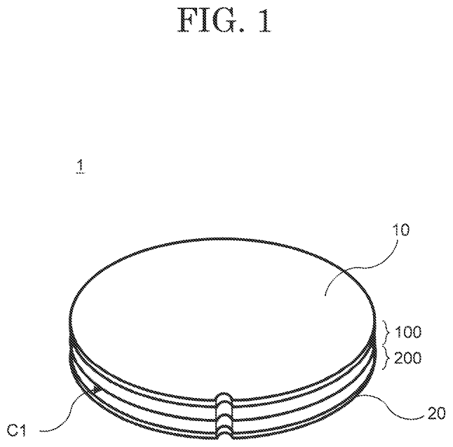

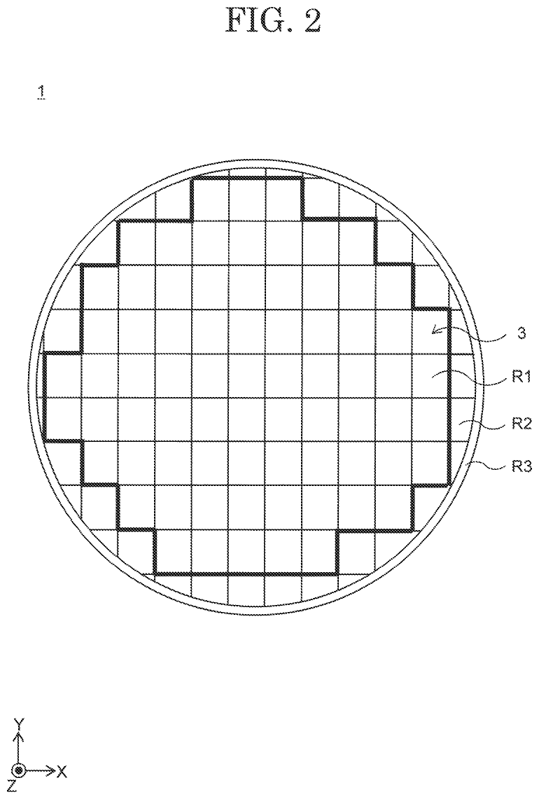

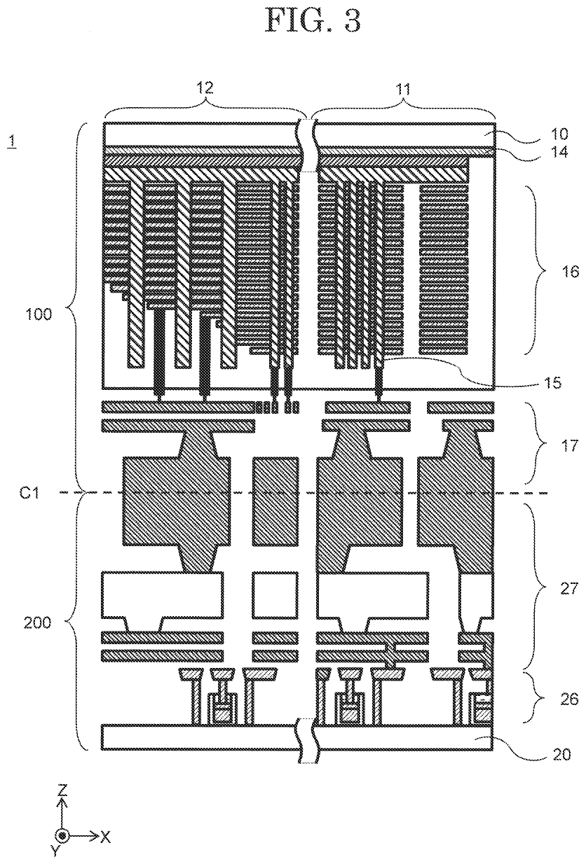

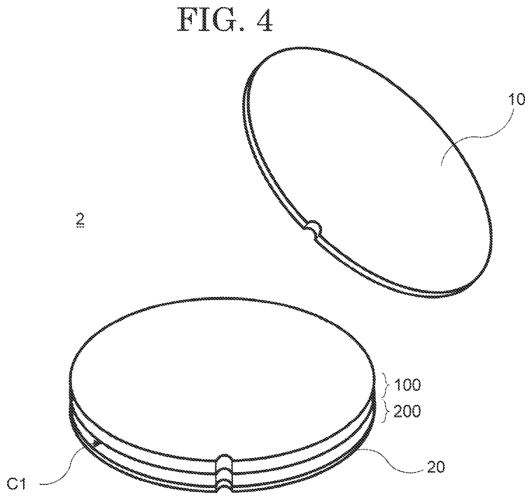

A configuration of a semiconductor memory device (bonded substrate) 1 according to the present embodiment will be described with reference to FIG. 1 to FIG. 4. FIG. 1 is a diagram showing an overall configuration of the semiconductor memory device 1. FIG. 2 is a top view showing a configuration of the semiconductor memory device 1. FIG. 3 is a cross-sectional view showing a basic configuration of the semiconductor memory device 1. FIG. 4 is a diagram showing an overall configuration of a semiconductor memory device 2.

The semiconductor memory device 1 includes a memory cell array chip 100 as a first circuit layer and a control circuit (CMOS circuit) chip 200 as a second circuit layer, as shown in FIG. 1. The memory cell array chip 100 and the control circuit chip 200 are connected at a connecting surface C1. Note that the first circuit layer and the second circuit layer are not particularly limited. Therefore, the semiconductor memory device of the embodiment may be referred to as a “semiconductor device”.

The semiconductor memory device 1 includes an effective chip area R1 for manufacturing a plurality of semiconductor chips 3 as shown in FIG. 2. The semiconductor memory device 1 includes a non-effective chip area R2 around the effective chip area R1, which is an offcut less than the size of the semiconductor chip 3. The effective chip area R1 is located on the center side of the semiconductor memory device 1 and has a shape that is close to a circle in a plan view. The non-effective chip area R2 is located on the end side of the semiconductor memory device 1 and has a shape close to a ring in a plan view. The non-effective chip area R2 circularly surrounds the effective chip area R1 in a plan view. The effective chip area R1 includes the device, for example, the memory cell array and/or the control circuit which is electrically connected. On the other hand, the non-effective chip area R2 may not include the device, for example, memory cell array or the control circuit. Even if there is wiring or the like in the non-effective chip area R2, it is not electrically connected and cannot function as a chip.

FIG. 2 further shows a position of a laser irradiation area R3, which will be described later. The laser irradiation area R3 is arranged in the non-effective chip area R2. The laser irradiation area R3 does not overlap with the effective chip area R1. The laser irradiation area R3 is located at the end side of the semiconductor memory device 1 and has a ring shape in a plan view. The laser irradiation area R3 circularly surrounds the effective chip area R1 in a plan view. The laser irradiation area R3 is arranged in part of the non-effective chip area R2, but may be arranged in all of the non-effective chip area R2.

### [Structure of Control Circuit Chip]

The control circuit chip 200 includes a substrate 20, a plurality of transistors 26 forming the control circuit, and a circuit-side wiring layer 27 as shown in FIG. 3. The plurality of transistors 26 is formed on the substrate 20 and is electrically connected to the circuit-side wiring layer 27 on the opposite side from the substrate 20. A connecting terminal for connecting with the memory cell array chip 100 is arranged on the connecting surface C1 of the circuit-side wiring layer 27 on the opposite side from the substrate 20. The substrate 20 may be a semiconductor wafer, such as a silicon substrate.

### [Structure of Memory Cell Array Chip]

The memory cell array chip 100 includes a substrate 10, a porous layer 14, a plurality of electrode layers 16, a plurality of semiconductor pillars 15, and a memory-side wiring layer 17 as shown in FIG. 3. The electrode layers 16 are alternately stacked with the insulating layers on the substrate 10 via the porous layer 14. Each of the semiconducting pillars 15 is arranged so as to penetrate through the plurality of stacked electrode layers 16 in the direction perpendicular to the substrate 10. Each of the semiconductor pillars 15 is combined with the plurality of electrode layers 16 via the insulating layer to function as a plurality of transistors including memory cells. That is, the plurality of transistors including memory cells is three-dimensionally arranged in a memory cell array area 11 (upper right portion in FIG. 3). The semiconductor pillars 15 are electrically connected to a source line at one end (the substrate 10 side) and to the memory-side wiring layer 17 at the other end (opposite to the substrate 10 side). A connecting terminal for connecting with the control circuit tip 200 is arranged on the connecting surface C1 of the memory-side wiring layer 17 opposite to the substrate 10.

A contact area 12 (upper left portion in FIG. 3) is arranged on the substrate 10 in parallel with the memory cell array area 11. Terminal portions of the plurality of electrode layers 16 are respectively pulled out in a staircase pattern in the contact area 12. Each terminal portion is connected to wirings arranged in the vertical direction through a contact hole opened in an insulating film. These wirings arranged in the vertical direction are electrically connected to the memory-side wiring layer 17 and are connected to the control circuit chip 200 via the connecting terminal.

The substrate 10 may be a semiconductor wafer, such as a silicon substrate. For example, the porous layer 14 is preferably made of a porous epitaxially grown silicon layer, or a porous polysilicon layer containing low-resistance boron. The porous layer 14 is arranged between the substrate 10 and the plurality of electrode layers 16. The substrate 10 of the semiconductor memory device 1 according to the present embodiment is finally separated through the porous layer 14 in the manufacturing process of the semiconductor memory device, thereby manufacturing the semiconductor memory device 2 as shown in FIG. 4. The substrate 10 and the porous layer 14 may be removed from the semiconductor memory device 2, and then the surface of the semiconductor memory device may be cleaned, planarized, and an external terminal may be formed as needed. The semiconductor memory device 2 may be divided into individual pieces to form the semiconductor chips 3. The separated substrate 10 may be reused by removing the remaining porous layer 14 and the like.

### [Configuration of Porous Layer]

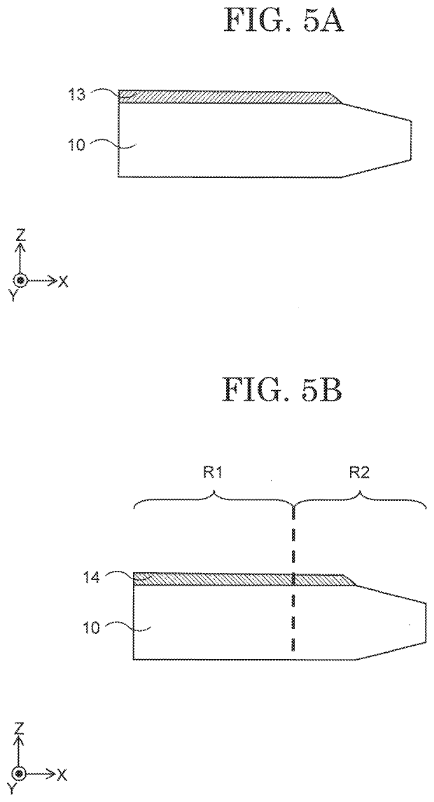

Configurations and forming methods of a silicon layer 13 and the porous layer 14 will be described in FIG. 5A and FIG. 5B. FIG. 5A is a diagram showing a configuration and a forming method of the silicon layer 13. FIG. 5B is a diagram showing a configuration and a forming method of the porous layer 14. First, the silicon layer 13 having a resistance lower than that of the substrate 10 is formed on substantially the entire surface of the substrate 10 on which the memory cells are arranged, as shown in FIG. 5A. For example, the silicon layer 13 is an epitaxially grown silicon layer or a polysilicon layer containing boron (B).

For example, the silicon layer 13 may be formed by an LP-CVD method. The low resistance silicon layer 13 with a thickness of about 100 nm to 20000 nm may be formed on the substrate 10 at a deposition temperature of around 800° C. by the LP-CVD method. In the case where the silicon layer 13 is formed by the LP-CVD method, a silicon layer may also be formed on the back surface side of the substrate 10. In this case, the silicon layer on the back surface side may be removed by a wet-etching method or the like.

For example, the silicon layer 13 may be formed by a PE-CVD method. The low resistance silicon layer 13 may be formed by forming an amorphous silicon layer with a thickness of about 100 nm to 20000 nm at a deposition temperature around 500° C. by the PE-CVD method, and then performing crystallization and activation by annealing at 850° C.

In addition, the low resistance silicon layer 13 may be formed on the substrate 10 by ion-implanting impurities into the substrate 10 and then performing activation by annealing. For example, the low resistance silicon layer 13 may be formed on the substrate 10 as the silicon layer 13 with a thickness of about 100 nm to 20000 nm.

Next, for example, the low resistance silicon layer 13 is made porous by an anodization method to form a low resistance porous layer 14 as shown in FIG. 5B. The substantially entire surface of the silicon layer 13 is made porous to form the porous layer 14 in the present embodiment. However, the present disclosure is not limited to this, and the low resistance porous layer 14 may be formed to the outer side of the effective chip area R1 for manufacturing the semiconductor chip 3 to be described later.

In addition, the surface of the substrate 10 may be made low in resistance and porous by the anodization method or the like to form the low resistance porous layer 14. For example, the substrate 10 may be a P-type single-crystal Si substrate with a specific resistance of 0.01Ω·cm, and the low resistance porous layer 14 may be formed by performing the anodization in an HF solution. For example, the anodization conditions may be current density: 5 (mA·cm⁻²), anodization solution:HF:H₂O:C₂H₅OH=1:1:1, time: 12 (minutes), thickness of the porous Si: 10 (μm), Porosity: 15 (%).

In the case of the silicon substrate, the impurity concentration is related to the resistance of the substrate, and the higher the impurity concentration, the lower the resistance. For example, the concentration of the impurity in the substrate 10 is preferably 1×10¹⁴ cm⁻³ or more and 1×10¹⁶ cm⁻³ or less, and the concentration of the impurity in the porous layer 14 is preferably 1×10¹⁷ cm⁻³ or more and 1×10¹⁹ cm⁻³ or less, in the present embodiment. The resistance of the substrate 10 is preferably 10Ω cm or more and 20Ω cm or less, and the resistance of the porous layer 14 is preferably 0.015Ω cm or more and about 0.15Ω cm or less. The resistance of the porous layer 14 is preferably 100 times or more smaller than the resistance of the substrate 10, in the present embodiment.

The wavelength dependence of the optical absorptance of each of the substrate 10 and the porous layer 14 is different in the present embodiment. While the substrate 10 has a low absorptivity with respect to a wavelength of 1 μm or more, since the porous layer 14 is formed of a low resistance silicon layer, the longer the wavelength, the higher the absorptivity for a wavelength of 1 μm or more. That is, the absorption coefficient of the porous layer 14 is larger than the absorption coefficient of the substrate 10 at the wavelength of 1 μm or more. Therefore, although infrared light energy with a wavelength of 1 μm or more is transmitted through the substrate 10, it is absorbed by the porous layer 14.

### [Substrate Processing Apparatus]

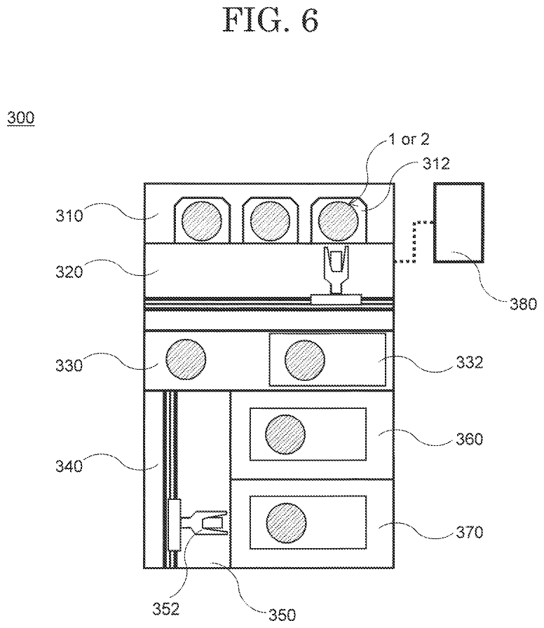

A substrate processing apparatus 300 according to the present embodiment will be described with reference to FIG. 6.

FIG. 6 is a top view showing a basic configuration of the substrate processing apparatus. The substrate processing apparatus 300 includes a cassette mounting table 310, a wafer transport device 320, a buffer station 330, and a processing station 340 as shown in FIG. 6.

The cassette mounting table 310 includes a plurality of cassettes 312 that houses the semiconductor memory device 1 or the semiconductor memory device 2. The buffer station 330 exchanges the semiconductor memory device 1 and the semiconductor memory device 2 before and after the substrate processing. The wafer transport device 320 transports the semiconductor memory device 1 housed in the cassette 312 before the substrate processing from the cassette mounting table 310 to the buffer station 330, and transports the semiconductor memory device 2 and the substrate 10 after the substrate processing from the buffer station 330 to the cassette mounting table 310. The buffer station 330 includes a wafer alignment device 332 that performs alignment of the semiconductor memory device 1 before the substrate processing. The wafer alignment device 332 performs alignment of a notch of the semiconductor memory device 1.

The processing station 340 includes a transport device 350, a first processing apparatus 360, and a second processing apparatus 370. The transport device 350 transports the semiconductor memory device 1 from the buffer station 330 to the first processing apparatus 360 and the second processing apparatus 370 in this order, and transports the semiconductor memory device 2 and the substrate 10 after the substrate processing from the second processing apparatus 370 to the buffer station 330.

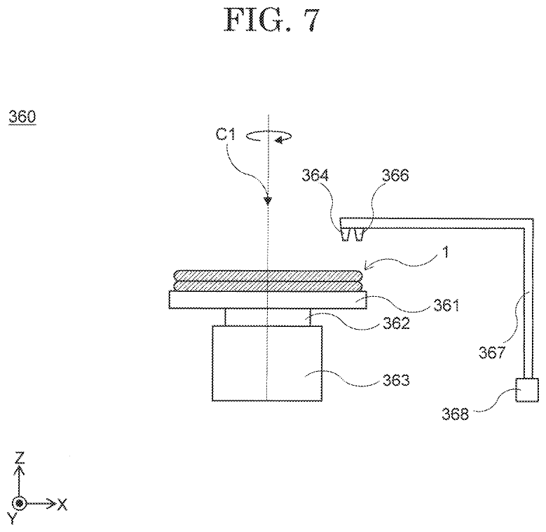

FIG. 7 is a side view showing a basic configuration of the first processing apparatus 360. The first processing apparatus 360 includes a stage 361, a laser irradiation device 364, and a position detection device 366. The stage 361 is circular and holds a wafer-shaped (disk-shaped) semiconductor memory device 1. The stage 361 may adsorb the entire surface of the semiconductor memory device 1 using a vacuum chuck. The semiconductor memory device 1 is arranged such that the substrate 20 is facing downward (the stage 361 side) and the substrate 10 facing upward (the side opposed to the stage 361). In addition, the stage 361 includes a lift that raises and lowers the semiconductor memory device 1 in the vertical direction (Z-direction) with respect to the stage 361. By the lifting and lowering operation of the lift, the semiconductor memory device 1 before the substrate processing can be carried into the first processing apparatus 360, and the semiconductor memory device 1 after the substrate processing can be carried out from the first processing apparatus 360.

The stage 361 includes a rotator 362 and a controller (control circuit) 363. The stage 361 is rotated about a vertical shaft including a center C1 by the rotator 362. As the stage 361 rotates, the semiconductor memory device 1 held by the stage 361 rotates about the center C1. The rotational operation and the rotational speed of the stage 361 driven by the rotator 362 are controlled by the controller 363. However, the present disclosure is not limited to this, the rotational operation and the rotational speed of the stage 361 driven by the rotator 362 may be controlled by a controller (control circuit) 380 of the substrate processing apparatus 300.

The laser irradiation device 364 and the position detection device 366 are arranged above the stage 361. The position detection device 366 detects an outer peripheral position and a thickness of the semiconductor memory device 1. Since the position detection device 366 detects the outer peripheral position and the thickness of the semiconductor memory device 1, it is possible to more accurately control the position of the laser irradiation area R3. The position detection device 366 is integrated with the laser irradiation device 364. However, the present disclosure is not limited to this, and the position detection device 366 may be separate from the laser irradiation device 364.

The laser irradiation device 364 irradiates the laser irradiation area R3 of the semiconductor memory device 1 with a laser. The laser is focused and irradiated onto the porous layer 14 of the semiconductor memory device 1. The laser irradiation device 364 irradiates a high-frequency pulsed laser oscillated by a laser oscillator (not shown). For example, the laser is preferably an infrared pulsed laser with a wavelength of 1 μm or more, and is preferably a carbon dioxide laser (CO₂ laser). The porous layer 14 with low resistance is ablated by the laser radiation.

The laser irradiation device 364 includes a driver 367 and a controller (control circuit) 368. The laser irradiation device 364 moves in the radial direction above the stage 361 by the driver 367. The laser irradiation device 364 can move the width of the laser irradiation area R3 of the semiconductor memory device 1 from at least the end of the semiconductor memory device 1 toward the center. As the laser irradiation device 364 moves while the stage 361 rotates, the laser irradiation device 364 can irradiate the stage 361 with the laser along a spiral trajectory. The moving operation and the moving speed of the laser irradiation device 364 driven by the driver 367 and the laser power of the laser irradiation device 364 are controlled by the controller 368. However, the present disclosure is not limited to this, the moving operation and the moving speed of the laser irradiation device 364 driven by the driver 367 and the laser output of the laser irradiation device 364 may be controlled by the controller 380 of the substrate processing apparatus 300.

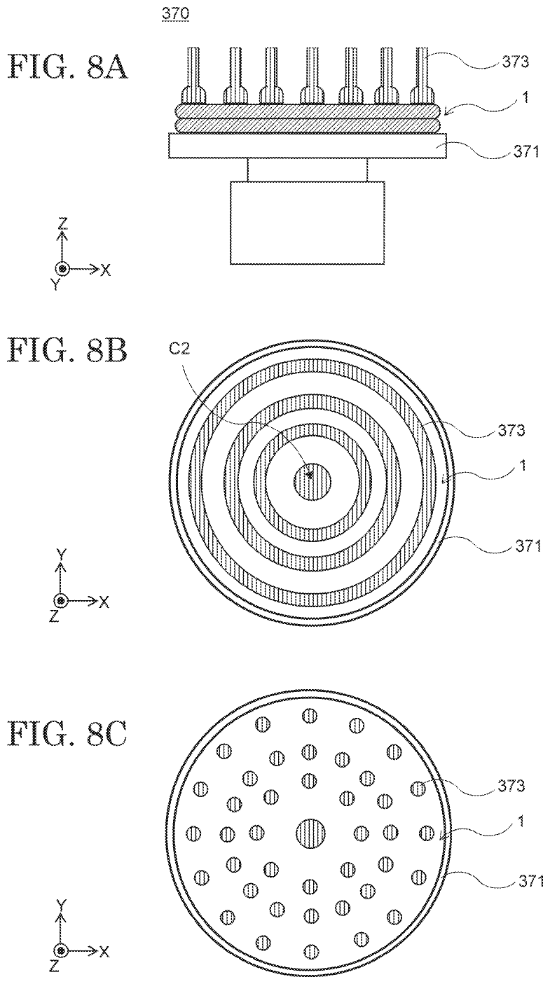

FIG. 8A is a side view showing a basic configuration of the second processing apparatus 370. FIG. 8B is a top view showing a basic configuration of the second processing apparatus 370. The second processing apparatus 370 includes a stage 371 and a plurality of pads 373. The stage 371 has a circular shape and holds a wafer-shaped (disk-shaped) semiconductor memory device 1. The stage 371 may adsorb the entire surface of the semiconductor memory device 1 using the vacuum chuck. The center of the semiconductor memory device 1 is preferably arranged at a center C2 of the stage 371. The semiconductor memory device 1 is arranged such that the substrate 20 is facing downward (the stage 371 side) and the substrate 10 is facing upward (the side opposed to the stage 371). In addition, the stage 371 includes a lift that raises and lowers the semiconductor memory device 1 in the vertical direction (Z-direction) with respect to the stage 371. By the lifting and lowering operation of the lift, the semiconductor memory device 1 before the substrate processing can be carried into the second processing apparatus 370, and the semiconductor memory device 2 and the substrate 10 after the substrate processing can be carried out from the second processing apparatus 370.

The plurality of pads 373 is arranged above the stage 371. The plurality of pads 373 has an annular shape and is arranged concentrically about the center C2 with respect to the circular stage 371 in a plan view. Each of the plurality of pads 373 includes a lift (not shown) that raises and lowers in the vertical direction (Z-direction) with respect to the stage 371, and a suction/pressurization port (not shown). The plurality of pads 373 may be arranged to be in contact with the substrate 10 of the semiconductor memory device 1 by the lifting and lowering operation. A contact surface of the plurality of pads 373 with the substrate 10 may be sucked or pressurized to the substrate 10 of the semiconductor memory device 1 by a suction or pressurization operation. For example, the pad 373 that sucks the substrate 10 of the semiconductor memory device 1 among the plurality of pads 373 may raise the substrate 10 in the vertical direction (Z-direction) with respect to the stage 371 by the lifting operation using the lift. The pad 373 that pressurizes the substrate 10 of the semiconductor memory device 1 among the plurality of pads 373 may press the substrate 10 in the vertical direction (Z-direction) against the stage 371 by the lowering operation using the lift. The lifting and lowering operation using the lift and the sucking or pressurizing operation using the suction/pressurization port of each of the plurality of pads 373 are independently controlled. That is, the pad 373 that performs the suction operation and the raising operation and the pad 373 that performs the pressure operation and the lowering operation may be mixed. The pad 373 arranged on the outer peripheral side of the semiconductor memory device 1 may perform the sucking and raising operation, and the pad 373 arranged on the center C2 side of the semiconductor memory device 1 may perform the pressurizing and lowering operation. From the pad 373 arranged on the outer peripheral side of the semiconductor memory device 1 to the pad 373 arranged on the center C2 side may be controlled by switching over time from the pressurizing and lowering operation to the sucking and raising operation. It is preferable that the substrate 10 of the pad 373 is made of a flexible rubber or the like.

FIG. 8C is a top view showing a basic configuration of the second processing apparatus 370 according to a modification. FIG. 8B shows that the plurality of pads 373 according to the present embodiment has an annular shape. However, the present disclosure is not limited to this, the pad 373 may be arranged concentrically in a dotted manner as shown in FIG. 8C. In this case, the plurality of pads 373 arranged on one circumference may be collectively controlled from the lifting operation and the suction or pressurizing operation.

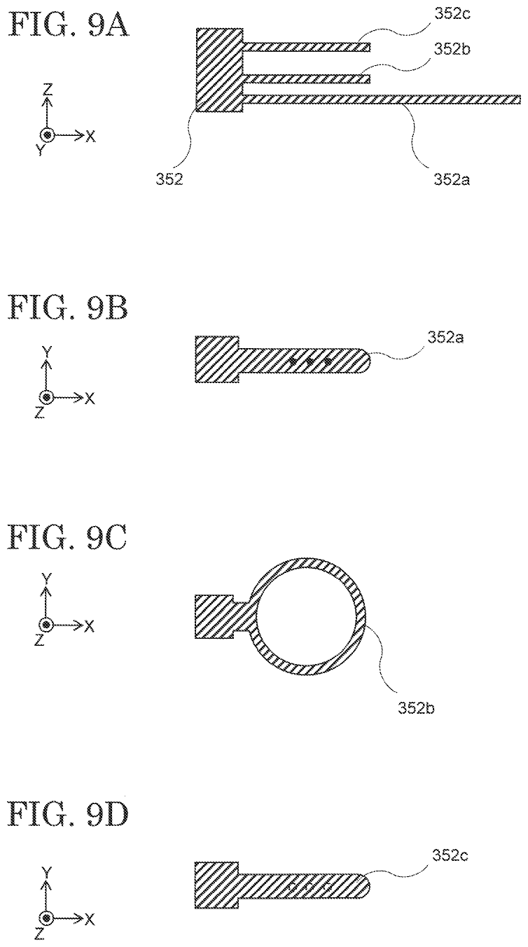

The transport device 350 includes a wafer hand 352 for carrying in and carrying out the semiconductor memory device 1, the semiconductor memory device 2, and the substrate 10 into and from the first processing apparatus 360 and the second processing apparatus 370. FIG. 9A is a side view showing a basic configuration of the wafer hand 352.

For example, the wafer hand 352 has a first arm 352a, a second arm 352b, and a third arm 352c. FIG. 9A shows a diagram that the first arm 352a is extending. However, the present disclosure is not limited to this, each of the first arm 352a, the second arm 352b, and the third arm 352c of the wafer hand 352 is extendable and retractable.

FIG. 9B is a top view showing a configuration of the first arm 352a. The first arm 352a can hold the semiconductor memory device 1 or the semiconductor memory device 2 by being inserted below the semiconductor memory device 1 or the semiconductor memory device 2 raised by the lift of the stage, and can be carried into and out from the first processing apparatus 360 or the second processing apparatus 370. The first arm 352a may have a suction hole on the upper surface, and the substrate 20 of the semiconductor memory device 1 or the semiconductor memory device 2 may be sucked and held by suction. FIG. 9B shows that the first arm 352a is in the form of a bar. However, the present disclosure is not limited to this, and the first arm 352a may stably hold the semiconductor memory device 1 or the semiconductor memory device 2.

FIG. 9C is a top view showing a configuration of the second arm 352b. The second arm 352b can hold the substrate 10 by being inserted below the substrate 10 after the substrate processing, which is sucked by the sucking and pressuring port of the plurality of pads 373 and raised by the lift, and carried out from the second processing apparatus 370. FIG. 9C shows that the second arm 352b has an annular shape. However, the present disclosure is not limited to this, the second arm 352b may stably hold the substrate 10 without interfering with the porous layer 14 remaining on the substrate 10.

FIG. 9D is a top view showing a configuration of the third arm 352c. The third arm 352c can hold the substrate 10 from above, which is carried out from the second processing apparatus 370 by the second arm 352b after the substrate processing. The third arm 352c may have a suction hole on the lower surface, and the substrate 10 after the substrate processing may be suction-held by suction. FIG. 9D shows that the third arm 352c is in the form of a bar. However, the present disclosure is not limited to this, the third arm 352c may be capable of stably holding the substrate 10. With the third arm 352c holding the substrate 10 from above, the substrate 10 can be reversed by pulling out the second arm 352b and rotating the third arm 352c.

### [Method for Separating Substrate]

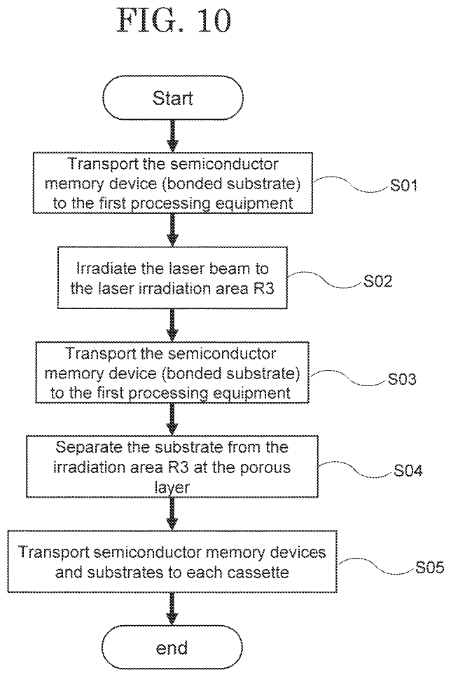

A method for separating a substrate for removing the substrate 10 and the porous layer 14 from the semiconductor memory device 1 using the substrate processing apparatus 300 according to the present embodiment will be described. The semiconductor memory device (semiconductor device) of the embodiment is manufactured using the method for separating a substrate described below. FIG. 10 is a flowchart illustrating the method for separating a substrate according to the present embodiment.

First, when the semiconductor memory device 1 is placed on the cassette 312 of the cassette mounting table 310, the wafer transport device 320 transports the semiconductor memory device 1 to the buffer station 330. The wafer alignment device 332 of the buffer station 330 performs alignment of the notch of the semiconductor memory device 1. The transport device 350 carries the semiconductor memory device 1 from the buffer station 330 into the first processing apparatus 360 using the first arm 352a of the wafer hand 352 (S01 in FIG. 10).

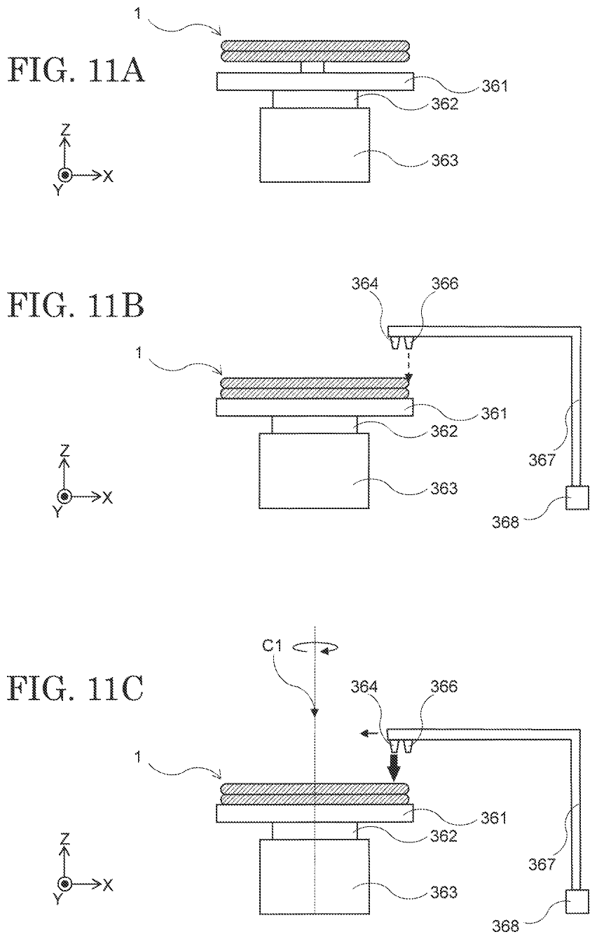

FIG. 11A to FIG. 11C are side views of the processing apparatus illustrating the method for separating a substrate according to the present embodiment. The semiconductor memory device 1 is arranged such that the substrate 10 on which the porous layer 14 is arranged is placed upward (the side opposed to the stage 361) on the stage 361 of the first processing apparatus 360, and the entire surface of the substrate 20 of the semiconductor memory device 1 is adsorbed to the stage 361 by sucking the vacuum chuck, as shown in 11A. The center of the semiconductor memory device 1 is preferably arranged at the center C1 of the stage 361.

The position detection device 366 detects the outer peripheral position and the thickness of the semiconductor memory device 1 as shown in FIG. 11B. The position of the laser irradiation area R3 is set from the outer peripheral position and the thickness of the semiconductor memory device 1 detected by the position detection device 366.

While the stage 361 is rotated by the rotator 362, the laser irradiation device 364 irradiates the laser irradiation area R3 of the semiconductor memory device 1 with a laser (S02 in FIG. 10) as shown in FIG. 11C. For example, the laser is preferably an infrared pulsed laser with a wavelength of 1 μm or more, and is preferably a carbon dioxide laser (CO₂ laser). The laser with a wavelength of 1 μm or more is transparent to the substrate 10. Therefore, by irradiating a laser from the substrate 10 side of the semiconductor memory device 1, the porous layer 14 located below the substrate 10 can be focused and irradiated.

By moving the laser irradiation device 364 above the stage 361 in the radial direction (arrow) by the driver 367, the laser irradiation device 364 irradiates the stage 361 with a laser along a spiral trajectory. The laser irradiation device 364 moves the width of the laser irradiation area R3 of the semiconductor memory device 1 from at least the end of the semiconductor memory device 1 toward the center. The laser irradiation device 364 irradiates the annular shaped laser irradiation area R3 of the semiconductor memory device 1 arranged on the stage 361 with a laser along a spiral trajectory.

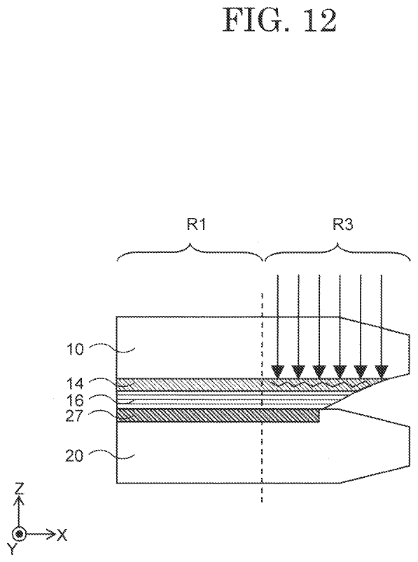

FIG. 12 is a cross-sectional view showing the laser irradiation area R3 of the semiconductor memory device 1 according to the present embodiment. The high resistance substrate 10 with few impurities absorbs almost no infrared light and does not react with light. On the other hand, the porous layer 14 with low resistance absorbs the infrared light and generates heat when irradiated with a laser, and local shear stresses are generated in the transverse direction (XY direction) due to rapid thermal expansion. Further, since the porous layer 14 has a void inside, it has high heat insulating property and low Young's modulus. Therefore, cracks can be easily generated inside the porous layer 14 or at the interface between the porous layer 14 and the upper or lower layers with low energy. The bonding force of the porous layer 14 in the laser irradiation area R3 decreases due to the cracks. In order to promote modification (reduction in bonding force) of the porous layer 14 by laser irradiation, it is preferable that the difference in resistance between the substrate 10 and the porous layer 14 and the difference in the optical absorptance be larger. In addition, the wavelength of the laser is transmitted without being absorbed in the substrate 10 with high resistance at a longer wavelength, and can be absorbed by the porous layer 14 with low resistance.

A configuration in which the two controllers 368 and 363 respectively control the rotational speed of the stage 361 of the first processing apparatus 360, the moving speed of the laser irradiation device 364, and the laser output (the frequency of the pulsed laser and the diameter of the laser spot) of the laser irradiation device 364 has been shown in the present embodiment. However, the present disclosure is not limited to this, and the rotational speed of the stage 361 of the first processing apparatus 360, the moving speed of the laser irradiation device 364, and the laser output (the frequency of the pulsed laser, the diameter of the laser spot) of the laser irradiation device 364 may be integrally controlled by the controller 380 of the substrate processing apparatus 300.

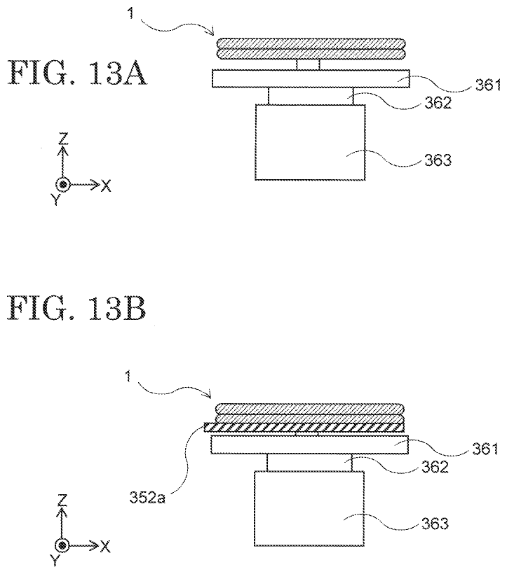

FIG. 13A and FIG. 13B are side views of the processing apparatus illustrating the method for separating a substrate according to the present embodiment. The suction of the vacuum chuck on the stage 361 is released, and the semiconductor memory device 1 is lifted from the stage 361 by the lift as shown in FIG. 13A.

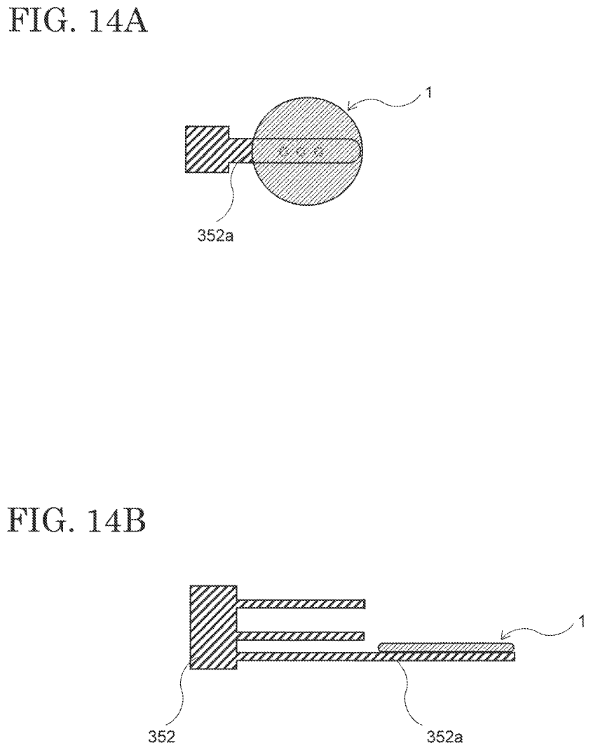

The first arm 352a of the wafer hand 352 is inserted below the semiconductor memory device 1 raised from the stage 361 by the lift, and the semiconductor memory device 1 is held, as shown in FIG. 13B. FIG. 14A and FIG. 14B are a top view and a side view of the wafer hand illustrating the method for separating a substrate according to the present embodiment. The first arm 352a has a suction hole on the upper surface, and sucks and holds the substrate 20 of the semiconductor memory device 1 by suction, as shown in FIG. 14A. The semiconductor memory device 1 is carried out from the first processing apparatus 360 by expanding, contracting and moving the first arm 352a, and the semiconductor memory device 1 is carried into the second processing apparatus 370 (S03 in FIG. 10), as shown in FIG. 14B.

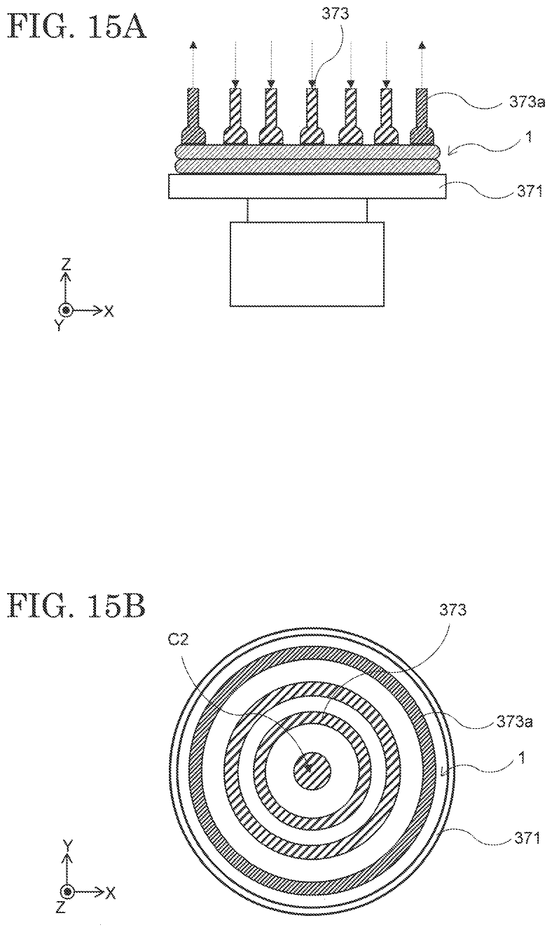

FIG. 15A and FIG. 15B are a side view and a top view of the processing apparatus illustrating the method for separating a substrate according to the present embodiment. The semiconductor memory device 1 is arranged such that the substrate 10 on which the porous layer 14 is arranged is placed upward (the side opposed to the stage 371) on the stage 371 of the second processing apparatus 370, and the entire surface of the substrate 20 of the semiconductor memory device 1 is adsorbed to the stage 371 by sucking the vacuum chuck, as shown in FIG. 15A and FIG. 15B. The plurality of pads 373 is arranged concentrically with respect to the semiconductor memory device 1 in a plan view and in contact with the substrate 10 of the semiconductor memory device 1. In this case, a pad 373a arranged on the outermost circumference of the semiconductor memory device 1 performs a sucking and raising operation, and the remaining pad 373 arranged on the center C2 side of the semiconductor memory device 1 performs a pressurizing and lowering operation. Since the porous layer 14 in the laser irradiation area R3 is modified (reduced bonding force) by laser irradiation, the sucking and raising operation of the pad 373a arranged on the outermost circumference and the pressurizing and lowering operation of the remaining pad 373 arranged on the center C2 side acts to uniformly peel off along the outer peripheral portion, and the substrate 10 starts to be separated from the modified porous layer 14 as a starting point.

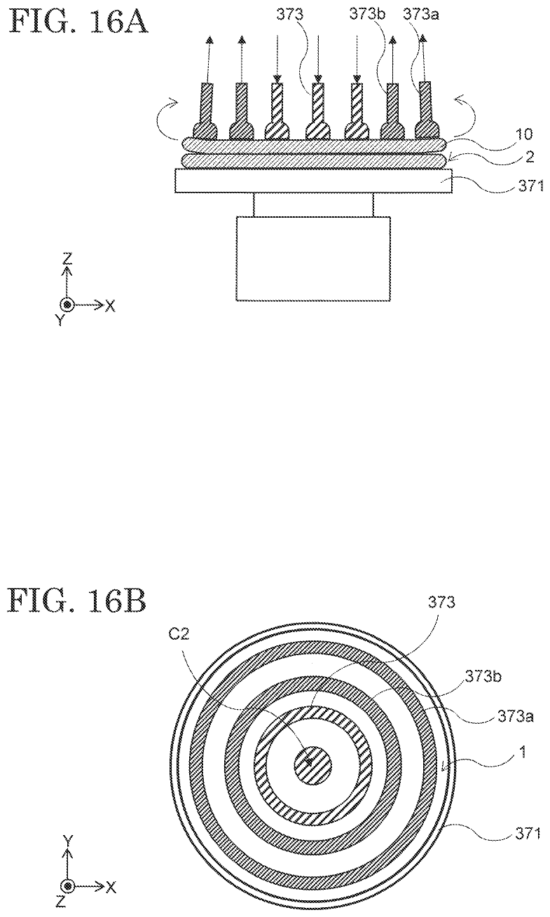

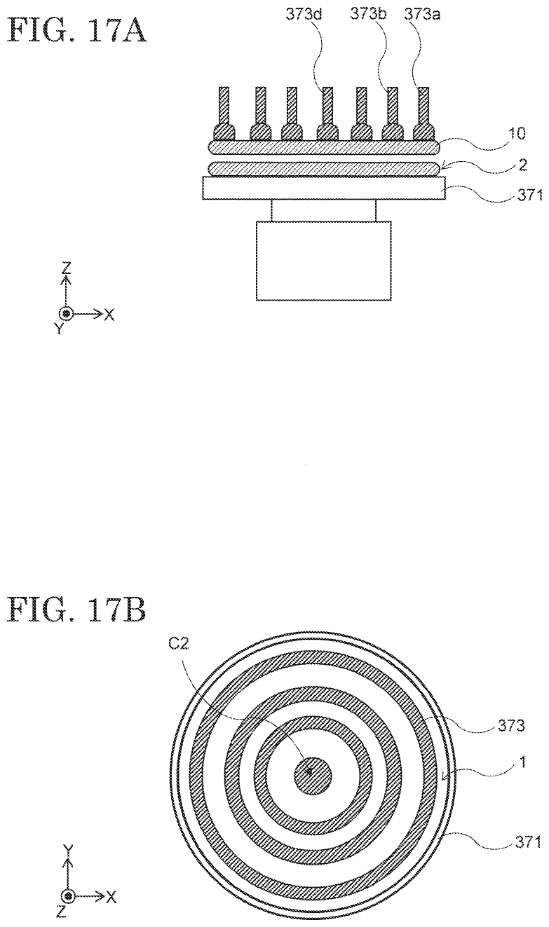

When the substrate 10 starts to be separated, a pad 373b adjacent to the pad 373a arranged on the outermost circumference is operated to be sucked and raised, and the remaining pad 373 arranged on the center C2 side of the semiconductor memory device 1 is operated to be pressed and lowered as shown in FIG. 16A and FIG. 16B. The substrate 10 is separated by the porous layer 14 (S04 in FIG. 10) by controlling the semiconductor memory device 1 by switching from the pressurizing and lowering operation to the sucking and raising operation in stages from the pad 373a on the outer peripheral side to a pad 373d on the center side of the semiconductor memory device 1 as shown in FIG. 17A and FIG. 17B.

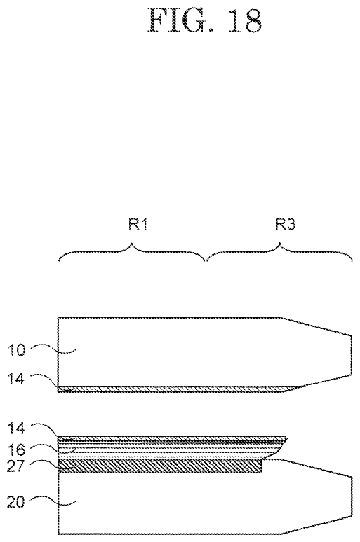

FIG. 18 is a cross-sectional view illustrating the separation of the substrate 10 from the semiconductor memory device 1 according to the present embodiment. The substrate 10 is separated in the porous layer 14 or at the interface of the porous layer 14 from the outer peripheral side to the center side of the semiconductor memory device 1 starting from the porous layer 14 in the modified laser irradiation area R3.

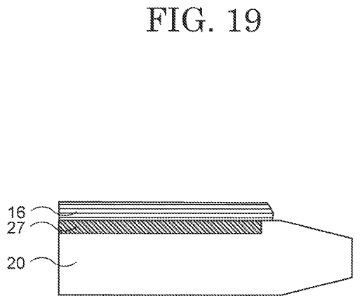

FIG. 19 is a cross-sectional view showing a configuration of the semiconductor memory device 2 according to the present embodiment. The substrate 10 and the porous layer 14 may be removed from the semiconductor memory device 2, and then the surface of the semiconductor memory device may be cleaned, and if necessary, planarized and an external terminal may be formed. The substrate 10 may be reused by removing and cleaning the porous layer 14 remains on the surface.

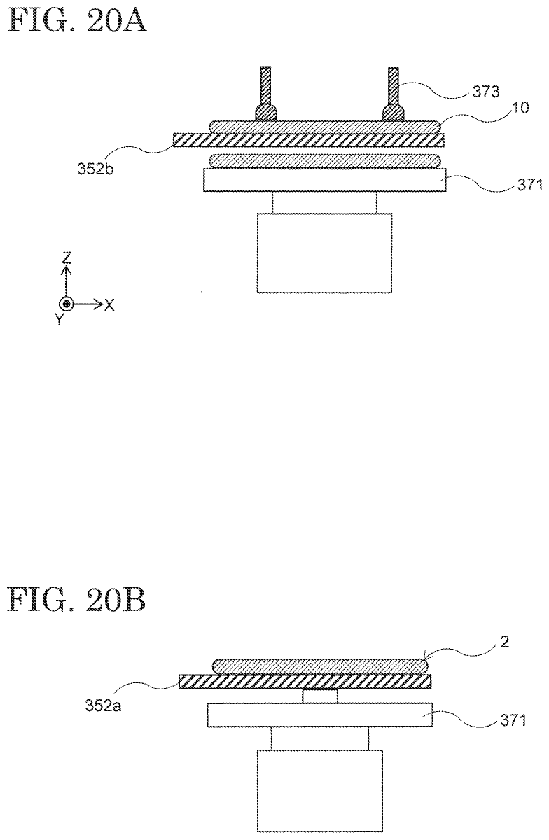

FIG. 20A and FIG. 20B are side views of the processing apparatus illustrating the method for separating a substrate according to the present embodiment. The substrate 10 is separated from the memory device 2 on the stage 371 by the sucking and raising operations of the plurality of pads 373, as shown in FIG. 20A. The substrate 10 is held by inserting the second arm 352b of the wafer hand 352 below the raised substrate 10 by the plurality of pads 373.

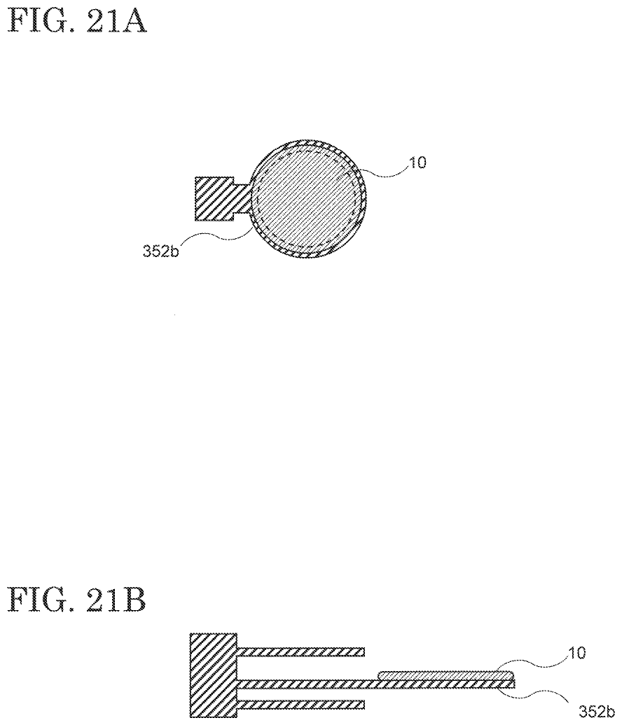

FIG. 21A and FIG. 21B are a top view and a side view of the wafer hand illustrating the method of separating substrate according to the present embodiment. Since the porous layer 14 remains partially on the lower surface of the substrate 10 (the surface on the semiconductor memory device 2 side), the second arm 352b is preferably annular shaped, as shown in FIG. 21A. The second arm 352b is extended and retracted to carry out the memory device 2 from the second processing apparatus 370, as shown in FIG. 21B.

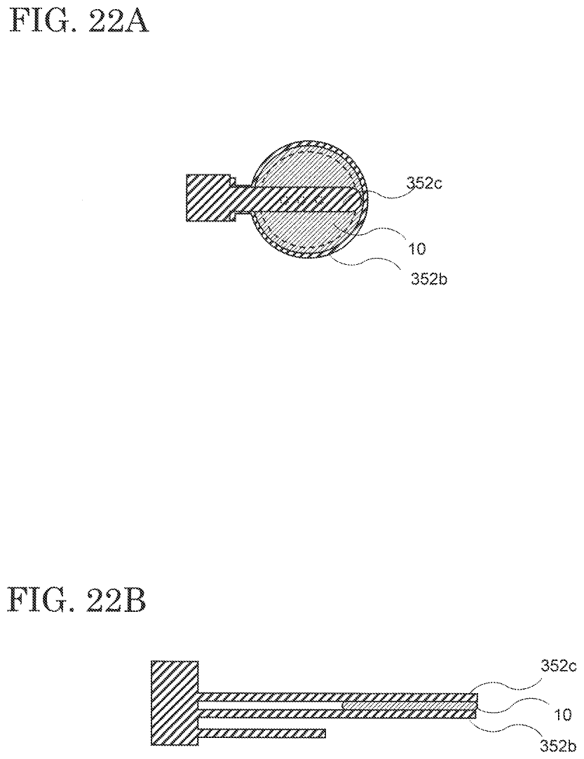

FIG. 22A and FIG. 22B are a top view and a side view of the wafer hand illustrating the method of separating substrate according to the present embodiment. The substrate 10 held by the second arm 352b is held by the third arm 352c as shown in the FIG. 22A and FIG. 22B. The third arm 352c has a suction hole on the lower surface, and sucks and holds the substrate 10 after the substrate processing from above by suction.

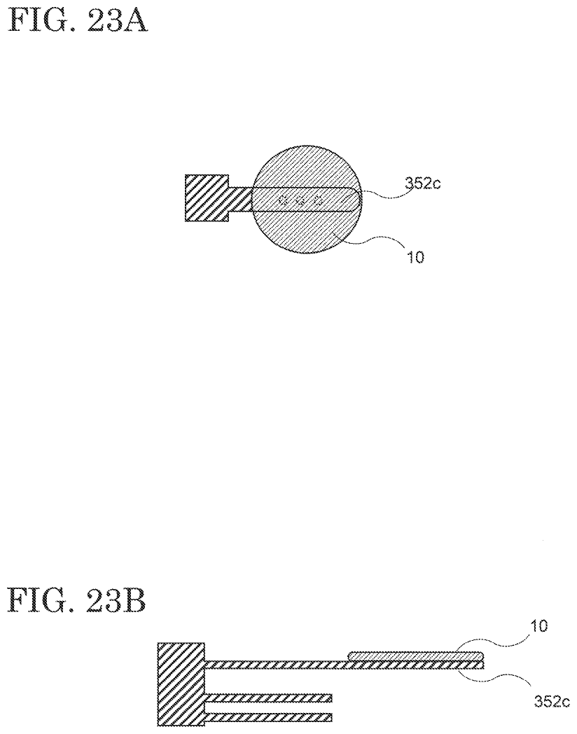

FIG. 23A and FIG. 23B are a top view and a side view of the wafer hand illustrating the method of separating substrate according to the present embodiment. The substrate 10 held by the third arm 352c reverses by pulling out the second arm 352b and rotating the third arm 352c, as shown in FIG. 23A and FIG. 23B. The transport device 350 uses the third arm 352c of the wafer hand 352 to transport the substrate 10 from the second processing apparatus 370 to the buffer station 330.

The suction of the vacuum chuck on the stage 371 is released, and the memory device 2 is raised from the stage 371 by the lift, as shown in FIG. 20B. The semiconductor memory device 2 is held by inserting the first arm 352a of the wafer hand 352 under the semiconductor memory device 2 raised from the stage 371 by the lift. The transport device 350 transports the semiconductor memory device 2 from the second processing apparatus 370 to the buffer station 330 using the first arm 352a of the wafer hand 352.

The wafer transport device 320 transports the semiconductor memory device 2 and the substrate 10 from the buffer station 330 to the cassette 312 of the cassette mounting table 310 (S05 of FIG. 10).

The porous layer 14 of the laser irradiation area R3 is irradiated with a laser, whereby the porous layer 14 in the laser irradiation area R3 is cracked and the bonding force is lowered in the method for separating a substrate according to the present embodiment. The substrate 10 can be separated without damaging the memory cell array and the CMOS circuit in the effective chip area R1 by separating the substrate 10 from the semiconductor memory device 1 with the modified (reduced bonding force) porous layer 14 as a starting point. Forming the mechanically fragile porous layer 14 on the substrate 10 makes it possible to keep the damage in the porous layer 14 when separating the substrate 10. As a result, the substrate 10 can be separated even by laser irradiation with a weak-energy, and stress damage and plastic deformation marks of the memory cell array chip 100 and the control circuit chip 200 caused by laser irradiation can be suppressed. Therefore, the method for separating a substrate according to the present embodiment can improve the manufacturing efficiency of the semiconductor memory device 2 and the reuse efficiency of the substrate 10.

What is claimed is:

1. A method of manufacturing a semiconductor device comprising:
forming a bonded substrate including an effective chip area by bonding a first chip including a first device layer on a first substrate via a porous layer and a second chip including a second device layer on a second substrate;
irradiating the porous layer in an ineffective chip area surrounding the effective chip area of the bonded substrate with laser light from the first substrate side; and
separating the first substrate from the bonded substrate from the porous layer in the ineffective chip area.

2. The method of manufacturing the semiconductor device according to claim 1, wherein
a wavelength of the laser light is a wavelength that transmits through the first substrate.

3. The method of manufacturing the semiconductor device according to claim 1, wherein
an absorption coefficient of the porous layer in the wavelength of the laser light is larger than an absorption coefficient of the first substrate in the wavelength of the laser light.

4. The method of manufacturing the semiconductor device according to claim 1, wherein
the porous layer includes a silicon layer with lower resistance than the first substrate.

5. The method of manufacturing the semiconductor device according to claim 1, wherein
the first device layer includes a memory cell array, and the second device layer includes a CMOS circuit.

6. The method of manufacturing the semiconductor device according to claim 1, wherein
the effective chip area includes a device that is electrically connected and the ineffective chip area includes a device that is not electrically connected.

7. A method for separating a substrate comprising:
irradiating a porous layer in an ineffective chip area surrounding an effective chip area of a bonded substrate with laser light from a first substrate side, the bonded substrate including the effective chip area and obtained by bonding the first substrate including the porous layer and the second substrate, and
separating the first substrate from the bonded substrate starting from the ineffective chip area of the porous layer.

8. The method for separating a substrate according to claim 7, wherein
a wavelength of the laser light is a wavelength that transmits through the first substrate.

9. The method for separating a substrate according to claim 7, wherein
an absorption coefficient of the porous layer in the wavelength of the laser light is larger than an absorption coefficient of the first substrate in the wavelength of the laser light.

10. The method for separating a substrate according to claim 7, wherein
the porous layer includes a silicon layer with lower resistance than the first substrate.

11. The method for separating a substrate according to claim 7, wherein
the first device layer includes a memory cell array, and the second device layer includes a CMOS circuit.

12. The method of manufacturing the semiconductor device according to claim 7, wherein
the effective chip area includes a device that is electrically connected and the ineffective chip area includes a device that is not electrically connected.

13. A substrate processing apparatus comprising:
a first processing chamber includes:
a first stage configured to rotate and configured to hold a bonded substrate including an effective chip area and obtained by bonding a first substrate including a porous layer and a second substrate,
a position detection part that detects a position of the bonded substrate;
a laser irradiation part that irradiates the porous layer in an ineffective chip area surrounding the effective area of the bonded substrate with laser light from the first substrate side; and
a stress application part that applies stress inward from the ineffective chip area of the porous layer.

14. The substrate processing apparatus according to claim 13, further comprising:
a second processing chamber includes:
a second stage configured to hold the bonded substrate and
a plurality of pads arranged above the stage; and
a transport device configured to transport the bonded substrate from the first processing chamber to the second processing chamber.

15. The substrate processing apparatus according to claim 14, wherein
the plurality of pads has an annular shape and is arranged concentrically with respect to the second stage in a plan view.

16. The substrate processing apparatus according to claim 14, wherein
the plurality of pads configured to be in contact with the first substrate of the bonded substrate and configured to be sucked or pressurized to the first substrate.

17. The substrate processing apparatus according to claim 13, wherein
a wavelength of the laser light is a wavelength that transmits through the first substrate.

18. The substrate processing apparatus according to claim 13, wherein
an absorption coefficient of the porous layer in the wavelength of the laser light is larger than an absorption coefficient of the first substrate in the wavelength of the laser light.

19. The substrate processing apparatus according to claim 13, wherein
the porous layer includes a silicon layer with lower resistance than the first substrate.

20. The substrate processing apparatus according to claim 13, wherein
the first substrate includes a memory cell array, and the second substrate includes a CMOS circuit.
